(19) United States
(12) Patent Application Publication
(10) Pub. No.: US 2013/0134447 A1
(43) Pub. Date: May 30, 2013

(54) LOW-LIGHT-EMITTING-ANGLE HIGH-LUMINANCE UV LED NAIL LAMP STRUCTURE AND LED LIGHT SOURCE MODULE THEREOF

(71) Applicants: Ching-Jen PAN, Zhudong Town (TW); Ming-Hung Chen, Zhudong Town (TW)

(72) Inventors: Ching-Jen PAN, Zhudong Town (TW); Ming-Hung Chen, Zhudong Town (TW)

(73) Assignee: Helio Optoelectronics Corporation, Hsinchu County (TW)

(21) Appl. No.: 13/343,844

(22) Filed: Jan. 5, 2012

(30) Foreign Application Priority Data
Nov. 29, 2011 (TW) 100222570

(51) Int. Cl. H01L 33/58

(52) U.S. Cl. 257/88; 257/E33.06

(57) ABSTRACT

A low-light-emitting-angle high-luminance ultraviolet (UV) light-emitting diode (LED) nail lamp structure and an LED light source module thereof are provided. The UV LED nail lamp structure includes a housing and an LED light source module. The LED light source module is provided in the housing and has a plurality of UV LEDs, wherein the light-emitting angle of each UV LED ranges between 25° and 80°. The UV LED nail lamp structure features high luminance and enhanced lighting effect.

### BACKGROUND OF THE INVENTION

1. Technical Field

The present invention relates to a low-light-emitting-angle high-luminance ultraviolet (UV) light-emitting diode (LED) nail lamp structure and an LED light source module thereof. More particularly, the present invention relates to a low-light-emitting-angle high-luminance ultraviolet (UV) light-emitting diode (LED) nail lamp structure for use in light therapy, and an LED light source module thereof

2. Description of Related Art

With the continuous advancement of LED technology, and thanks to their increasingly lower costs and energy saving features, LEDs have been extensively used in various lighting apparatuses. For example, LED lighting can be used to cure particular liquids, thereby forming a protective layer on industrial products. In the cosmetic industry, LED lighting can be used to cure UV curable gels and turn them into decorative or protective nail coatings. As a matter of fact, the conventional UV lamps in the foregoing applications have been gradually replaced by UV LEDs.

The conventional UV lamps have the following disadvantages. First of all, they emit UV radiation in the ultraviolet A (UVA), ultraviolet B (UVB), and ultraviolet C (UVC) bands, and long-term exposure to such UV radiation is carcinogenic. Secondly, as UV light tubes contain mercury, waste or damaged UV light tubes are harmful to human health and cause serious pollution. Last but not least, UV light tubes are bulky and therefore unsuitable for being carried around. UV LEDs are a perfect solution to the above problems not only because their light is closer to the less harmful visible light band, but also because of their easier post-consumer treatment and higher portability. Hence, UV LEDs have been viewed in the nail decoration industry as a safer UV light source that can be carried around more conveniently.

During the nail decoration process, the time required for curing an UV curable gel is related to the luminance of the UV LEDs in use. If the curing time is long, the performance of nail art will be hindered, and customer waiting time will be increased, thereby raising the costs of working time. In order to effectively shorten the curing time of UV curable gels and thereby reduce the associated costs, an LED nail lamp structure capable of providing high-luminance UV lighting is needed.

### SUMMARY OF THE INVENTION

The present invention provides a low-light-emitting-angle high-luminance ultraviolet (UV) light-emitting diode (LED) nail lamp structure that includes a housing and an LED light source module. The UV LED nail lamp structure of the present invention has a light-emitting angle that ranges between 25° and 80° and thus features higher luminance and better lighting effect when compared with the conventional UV LED nail lamp structure.

The present invention provides a low-light-emitting-angle high-luminance ultraviolet (UV) light-emitting diode (LED) nail lamp structure, comprising: a housing formed as a hollow housing and having an opening; and an LED light source module configured as an UV light source and provided on an upper side in the housing so as to project light downward, the LED light source module comprising: a circuit board; and a plurality of UV LEDs fixedly provided on and electrically connected to the circuit board, each said UV LED comprising: a supporting frame comprising a die pad and at least two electrodes; an LED chip provided in and connected to the die pad and electrically connected to the electrodes; a silicone filled in the die pad and covering the LED chip; and a lens connected to the supporting frame and covering the LED chip, such that a light-emitting angle of the UV LED ranges between 25° and 80°.

The present invention also provides a light-emitting diode (LED) light source module, configured as a low-light-emitting-angle high-luminance ultraviolet (UV) light source and applicable to an LED nail lamp structure, the LED light source module comprising: a circuit board; and a plurality of UV LEDs fixedly provided on and electrically connected to the circuit board, each said UV LED comprising: a supporting frame comprising a die pad and at least two electrodes; an LED chip provided in and connected to the die pad and electrically connected to the electrodes; a silicone filled in the die pad and covering the LED chip; and a lens connected to the supporting frame and covering the LED chip, such that a light-emitting angle of the UV LED ranges between 25° and 80°.

Implementation of the present invention at least involves inventive steps as follows:

1. The UV LED nail lamp structure is configured for better lighting effect.

2. The LED light source module is configured for higher luminance

The detailed features and advantages of the present invention will be described in detail with reference to the preferred embodiment so as to enable persons skilled in the art to gain insight into the technical disclosure of the present invention, implement the present invention accordingly, and readily understand the objectives and advantages of the present invention by perusal of the contents disclosed in the specification, the claims, and the accompanying drawings.

### BRIEF DESCRIPTION OF THE SEVERAL VIEWS OF THE DRAWINGS

FIG. 1 is an assembled perspective view of a low-light-emitting-angle high-luminance ultraviolet (UV) light-emitting diode (LED) nail lamp structure according to an embodiment of the present invention;

FIG. 2 is a sectional view taken along the line A-A in FIG. 1;

FIG. 3 is a perspective view of an LED light source module according to an embodiment of the present invention;

FIG. 4 is an exploded perspective view of an UV LED according to an embodiment of the present invention;

FIG. 5 is a sectional view taken the line B-B in FIG. 4; and

FIG. 6 is a diagram of a graph of UV LED light distribution curve according to an embodiment of the present invention.

### DETAILED DESCRIPTION OF THE EMBODIMENTS OF THE INVENTION

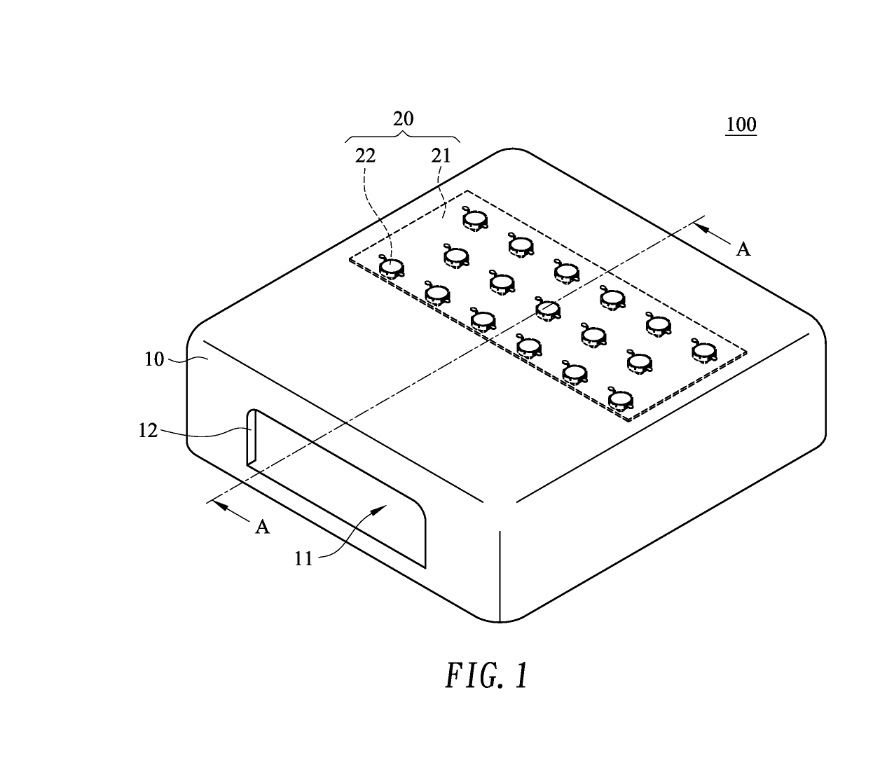

Referring to FIG. 1, a low-light-emitting-angle high-luminance ultraviolet (UV) light-emitting diode (LED) nail lamp structure 100 according to an embodiment of the present invention includes a housing 10 and an LED light source module 20.

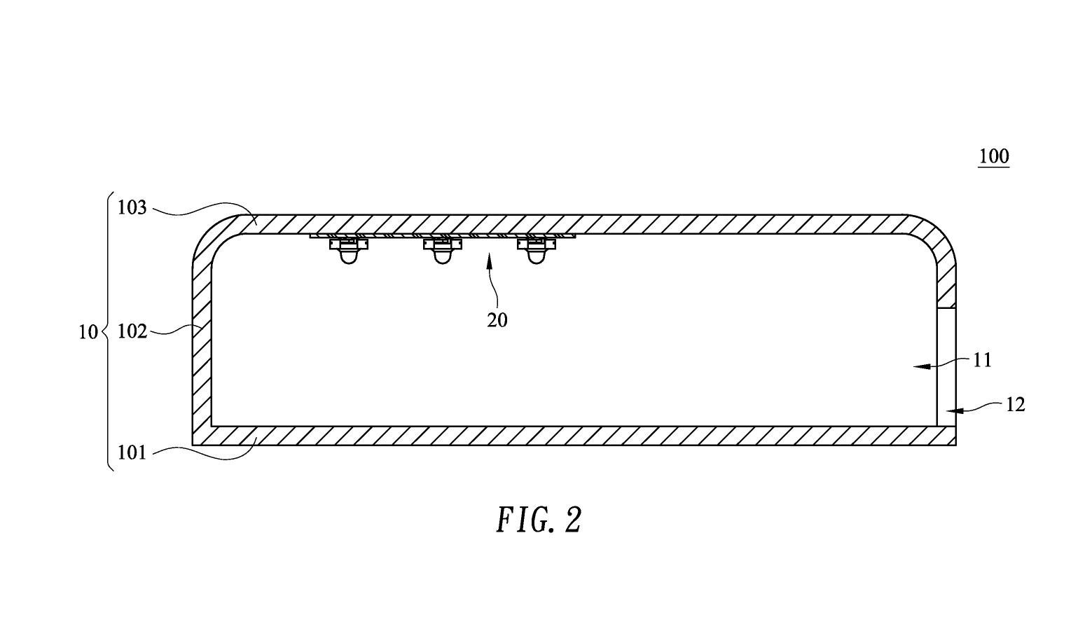

Referring to FIG. 2, the housing 10 includes a base plate 101, a lateral plate 102, and a top plate 103. The two ends of the lateral plate 102 are connected to the base plate 101 and the top plate 103 respectively such that the housing 10 forms a hollow housing. The housing 10 has an open hollow space 11 and an opening 12. The hollow space 11 is so configured that a human hand or foot inserted through the opening 12 can be received in the hollow space 11.

The LED light source module 20 is an UV light source. To facilitate irradiation of fingernails, the LED light source module 20 is typically provided inside the housing 10 and on the upper side thereof, i.e., on the inner side of the top plate 103 of the housing 10. This allows the LED light source module 20 to project light downward.

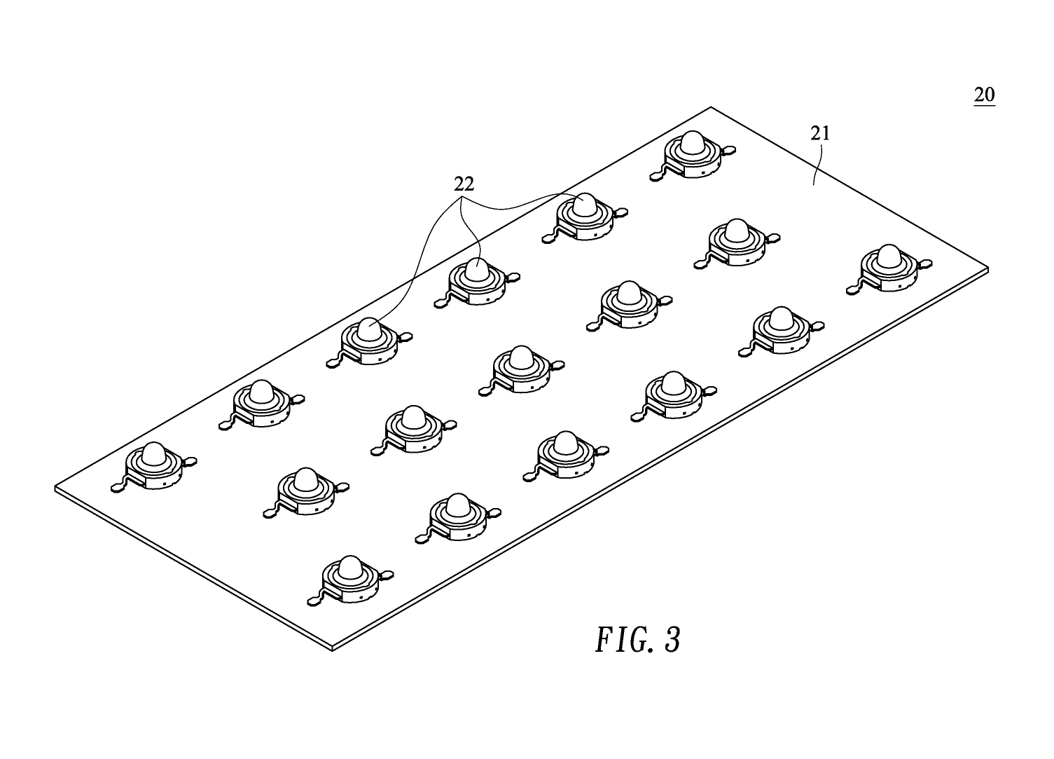

As shown in FIG. 3, the LED light source module 20 includes a circuit board 21 and a plurality of UV LEDs 22.

The circuit board 21 may have a modular design for easy inspection during the manufacturing process and for easy maintenance thereafter. In other words, the circuit board 21 can be composed of one or several boards. Generally, the circuit board 21 is an aluminum circuit board , a printed circuit board (PCB), a metal core printed circuit board (MCPCB) or a ceramic heat dissipating board.

The plural UV LEDs 22 are fixed on and electrically connected to the circuit board 21. The UV LEDs 22 can be distributed over the circuit board 21 at a fixed spacing in order to provide large-area illumination.

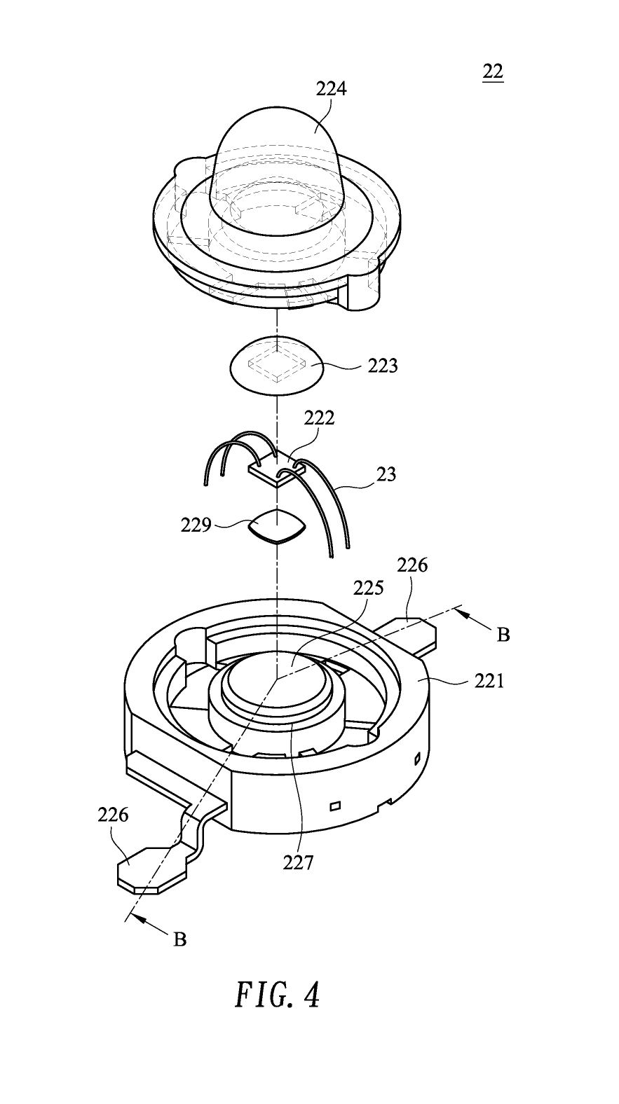

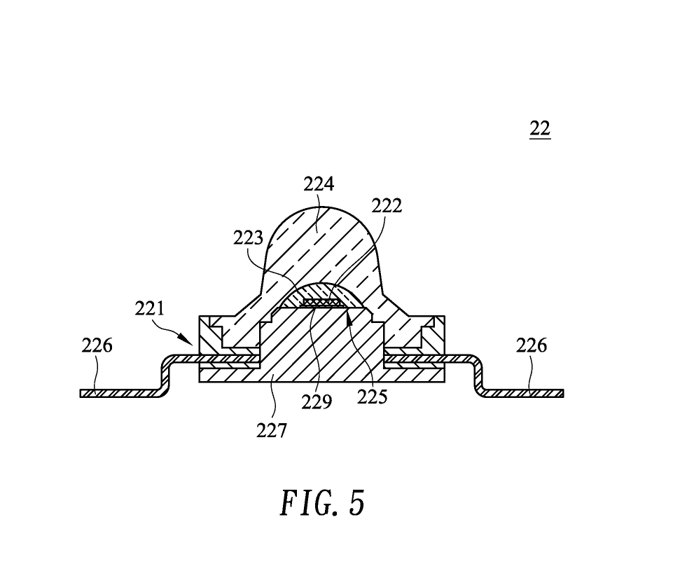

Referring to FIG. 4 and FIG. 5, each UV LED 22 includes a supporting frame 221, an LED chip 222, a silicone 223, and a lens 224.

The supporting frame 221 has a die pad 225 and at least two electrodes 226. The die pad 225 allows the LED chip 222 to be mounted thereon and allows the LED chip 222 to be electrically connected to the electrodes 226 by wires 23, so as for the LED chip 222 to receive electric power from an external power source by way of the electrodes 226. In most cases, the supporting frame 221 has a heat-conducting base 227, and the die pad 225 is a part of the heat-conducting base 227. The heat-conducting base 227 is made of a material with good heat dissipation properties, such as copper, tin, steel, iron, or like metals.

The LED chip 222 is disposed in and connected to the die pad 225 and is electrically connected to the electrodes 226 by means of the wires 23 to obtain the electric power needed. The LED chip 222 is connected to the die pad 225 by a silver-filled epoxy 229. The silver-filled epoxy 229, which is made by mixing silver powder into epoxy, is a bonding agent capable of both electrical and thermal conduction. In addition to connecting the LED chip 222 securely to the die pad 225, the silver-filled epoxy 229 is capable of heat transfer and therefore helps increase the service life and brightness of the LED chip 222 after enhancement of heat dissipation.

The silicone 223 is filled in the die pad 225 and covers the LED chip 222 and the wires 23. More specifically, the silicone 223 is filled into the die pad 225 after the LED chip 222 is placed in and connected to the die pad 225, so as for the silicone 223 to cover and thereby secure both the LED chip 222 and the wires 23. As the silicone 223 is a highly transparent, highly stable, and highly water-resistant encapsulant, it can protect the LED chip 222 from moisture and dust under various environmental conditions without compromising the output of light from the LED chip 222.

The lens 224 is connected to the supporting frame 221 and covers the LED chip 222. More specifically, the lens 224 is laid over the supporting frame 221 after the silicone 223 is filled in the die pad 225. The lens 224 is a silicone lens. When made of a silicone material, the lens 224 features a high refractive index, high temperature tolerance, high insulation ability, high chemical stability, high light-permeability, and high reliability and thus can avoid such drawbacks of the conventional encapsulants as material deterioration due to high temperature and the resultant attenuation of LED brightness. Besides, the lens 224 is a glass lens.

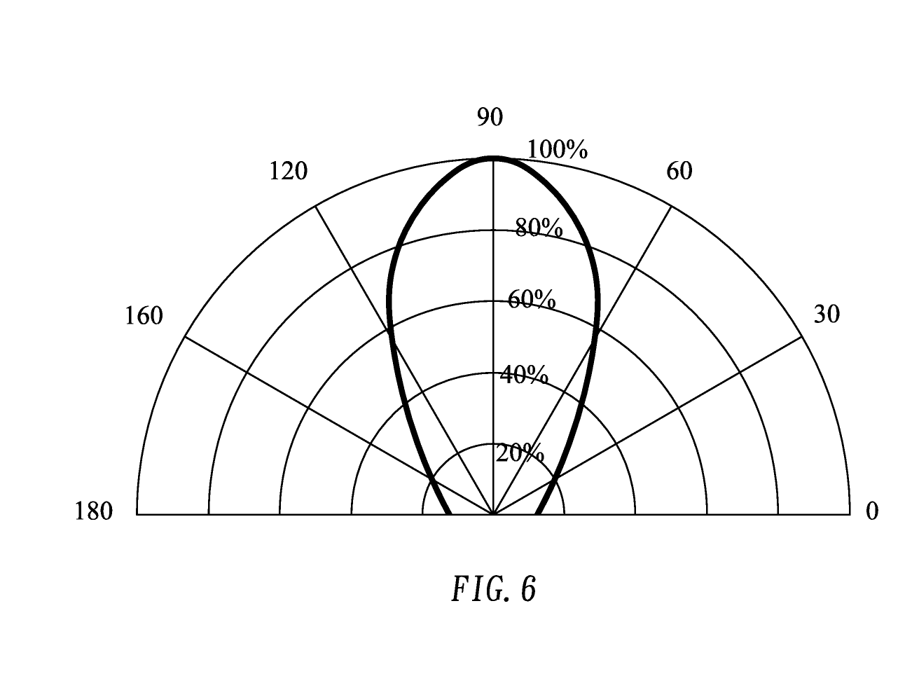

As shown in FIG. 6, the light-emitting angle of the lens 224 varies with design. As indicated by a diagram of a graph of UV LED light distribution curve of the UV LEDs 22, the lens 224 is designed to cause the UV LEDs 22 to have a light-emitting angle between 25° and 80°, especially a light-emitting angle of 70°. Hence, the UV LEDs 22 manifest optical properties, that is, a low-light-emitting-angle and high luminance. Furthermore, the LED light source module 20 is configured as a low-light-emitting-angle high-luminance UV light source and is effective in enhancing the luminance of the LED light source module 20.

In this embodiment, the LED nail lamp structure 100 is used in the following manner. Fingers or toes whose nails are coated with an UV curable gel are inserted into the hollow space 11 of the housing 10 through the opening 12. Then, the LED light source module 20 is turned on, allowing the LED light source module 20 to emit UV light and begin a curing process on the UV curable gel. As the UV curable gel is typically a photosensitizer-containing resin and, upon absorption of UV light, generates active free radicals or ions that trigger polymerization, cross-linking, and grafting reactions, UV light can turn the UV curable gel from the liquid state to the solid state within a few seconds so that the UV curable gel coating is fixed to the nails. Since the low-light-emitting-angle high-luminance UV LED nail lamp structure 100 in this embodiment provides high-luminance UV irradiation, the time required for curing the UV curable gel is shortened to thereby cut costs.

The features of the present invention are disclosed above by the preferred embodiment to allow persons skilled in the art to gain insight into the contents of the present invention and implement the present invention accordingly. The preferred embodiment of the present invention should not be interpreted as restrictive of the scope of the present invention. Hence, all equivalent modifications or amendments made to the aforesaid embodiment should fall within the scope of the appended claims.

What is claimed is:

1. A low-light-emitting-angle high-luminance ultraviolet (UV) light-emitting diode (LED) nail lamp structure, comprising:
a housing formed as a hollow housing and having an opening; and
an LED light source module configured as an UV light source and provided on an upper side in the housing so as to project light downward, the LED light source module comprising:
a circuit board; and
a plurality of UV LEDs fixedly provided on and electrically connected to the circuit board, each said UV LED comprising:
a supporting frame comprising a die pad and at least two electrodes;
an LED chip provided in and connected to the die pad and electrically connected to the electrodes;
a silicone filled in the die pad and covering the LED chip; and
a lens connected to the supporting frame and covering the LED chip, such that a light-emitting angle of the UV LED ranges between 25° and 80°.

2. The UV LED nail lamp structure of claim 1, wherein the circuit board is a printed circuit board (PCB), a metal core printed circuit board (MCPCB), or a ceramic heat dissipating board.

3. The UV LED nail lamp structure of claim 1, wherein the supporting frame has a heat-conducting base, and the die pad is a part of the heat-conducting base.

4. The UV LED nail lamp structure of claim 3, wherein the LED chip is connected to the die pad by a silver-filled epoxy.

5. The UV LED nail lamp structure of claim 1, wherein the lens is a silicone lens or a glass lens.

6. A light-emitting diode (LED) light source module, configured as a low-light-emitting-angle high-luminance ultraviolet (UV) light source and applicable to an LED nail lamp structure, the LED light source module comprising:
a circuit board; and
a plurality of UV LEDs fixedly provided on and electrically connected to the circuit board, each said UV LED comprising:
a supporting frame comprising a die pad and at least two electrodes;
an LED chip provided in and connected to the die pad and electrically connected to the electrodes;
a silicone filled in the die pad and covering the LED chip; and
a lens connected to the supporting frame and covering the LED chip, such that a light-emitting angle of the UV LED ranges between 25° and 80°.

7. The LED light source module of claim 6, wherein the circuit board is a printed circuit board (PCB), a metal core printed circuit board (MCPCB), or a ceramic heat dissipating board.

8. The LED light source module of claim 6, wherein the supporting frame has a heat-conducting base, and the die pad is a part of the heat-conducting base.

9. The LED light source module of claim 8, wherein the LED chip is connected to the die pad by a silver-filled epoxy.

10. The LED light source module of claim 6, wherein the lens is a silicone lens or a glass lens.
